(19) United States
(12) Patent Application Publication
(10) Pub. No.: US 2016/0365360 A1
(43) Pub. Date: Dec. 15, 2016

(54) Smoothing Device, Smoothing Method, Thin Film Transistor, Display Substrate and Display Device

(71) Applicant: BOE TECHNOLOGY GROUP CO., LTD., Beijing (CN)

(72) Inventors: Xiaolong LI, Beijing (CN); Huijuan ZHANG, Beijing (CN); Xiaoyong LU, Beijing (CN); Zheng LIU, Beijing (CN); Yucheng CHAN, Beijing (CN); Chunping LONG, Beijing (CN)

(21) Appl. No.: 15/095,649

(22) Filed: Apr. 11, 2016

(30) Foreign Application Priority Data
Jun. 11, 2015 (CN) 201510320622.7

(51) Int. Cl. H01L 27/12; H01J 37/32; H01L 21/67; H01L 29/786; H01L 21/3065

(52) U.S. Cl. CPC H01L 27/127; H01L 27/1222; H01L 29/78678; H01L 29/78696; H01L 21/3065; H01L 21/67069; H01J 37/32715; H01J 37/32669; H01J 2237/3344

(57) ABSTRACT

The present disclosure discloses a smoothing device, a smoothing method, a thin film transistor, a display substrate and a display device. The smoothing device comprises a cavity, a plasma generating component, a magnetic field generating component, an electric field generating component and a carrier located within the cavity. The plasmas generated by the plasma generating component are subjected to the Lorentz force parallel to the surface of the object to be smoothed under the effect of the magnetic field generated by the magnetic field generating component, and subjected to an electric field force in the direction perpendicular to the surface of the object to be smoothed and pointing to the object to be smoothed under the effect of the electric field generated by the electric field generating component.

### RELATED APPLICATIONS

The present application claims the benefit of Chinese Patent Application No. 201510320622.7, filed on Jun. 11, 2015, the entire disclosure of which is incorporated herein by reference.

### FIELD

The present disclosure relates to the field of display technologies, and particularly to a smoothing device, a smoothing method, a thin film transistor, a display substrate and a display device.

### BACKGROUND

In an existing display device, surface roughness of certain film layers would influence the performance of the display device. For example, in an existing thin film transistor (TFT) which employs a polysilicon layer as the active layer, since there are protrusions at the boundary (i.e. grain boundary) where the grains in the polysilicon layer converge, which result in large surface roughness of the polysilicon layer, i.e. the active layer has large surface roughness, the TFT has a large leakage current. Moreover, in order to smooth the surface roughness of the active layer, it is required to form a thick gate insulating layer. However, the thick gate insulating layer would decrease the reaction speed, driving current and storage capacitance of the TFT, and further make the drift phenomenon of the threshold voltage become apparent.

Currently, the existing method for reducing the surface roughness of the polysilicon layer is generally etching the polysilicon layer using an acid solution. However, the acid solution would also etch the concave positions in the polysilicon layer simultaneously with etching the convex positions at the grain boundary in the polysilicon layer, thereby damaging the integral surface of the polysilicon layer, further causing impact on the performance of the TFT.

Therefore, how to provide a novel device for decreasing surface roughness is a technical problem desiderated to be solved by those skilled in the art.

### SUMMARY

In view of this, the embodiments of the present disclosure provide a smoothing device, a smoothing method, a thin film transistor, a display substrate and a display device for at least alleviating or eliminating one or more of the existing technical problems mentioned above.

Therefore, the embodiments of the present disclosure provide a surface roughness smoothing device comprising a cavity, a plasma generating component, a magnetic field generating component, an electric field generating component and a carrier located within said cavity;

said carrier is used for carrying an object to be smoothed;

said plasma generating component is used for generating plasmas within said cavity;

said magnetic field generating component is used for generating a magnetic field within said cavity which is parallel to a surface of said object to be smoothed such that said plasmas are subjected to the Lorentz force in a direction parallel to the surface of said object to be smoothed;

said electric field generating component is used for generating an electric field within said cavity which is perpendicular to the surface of said object to be smoothed such that said plasmas are subjected to an electric field force in a direction perpendicular to the surface of said object to be smoothed and pointing to said object to be smoothed.

In a possible implementation, the aforesaid device provided by the embodiments of the present disclosure further comprises a control component;

said control component is used for controlling said magnetic field generating component to enhance an intensity of said magnetic field when said plasmas approach the surface of said object to be smoothed, and simultaneously controlling said electric field generating component to decrease an intensity of said electric field.

In a possible implementation, in the aforesaid device provided by the embodiments of the present disclosure, said magnetic field generating component comprises: a first electromagnetic coil and a second electromagnetic coil located at an outer surface of said cavity, and a first power source electrically connected to said first electromagnetic coil and a second power source electrically connected to said second electromagnetic coil; said first electromagnetic coil is symmetric to said second electromagnetic coil with respect to a central axis of said cavity;

said first power source is used for loading a first electric signal for said first electromagnetic coil to enable said first electromagnetic coil to generate a magnetic field;

said second power source is used for loading a second electric signal for said second electromagnetic coil to enable said second electromagnetic coil to generate a magnetic field in a direction opposite to that of the magnetic field generated by said first electromagnetic coil.

In a possible implementation, in the aforesaid device provided by the embodiments of the present disclosure, said control component is specifically used for controlling said first power source to increase an intensity of said first electric signal and controlling said second power source to increase an intensity of said second electric signal when said plasmas approach the surface of said object to be smoothed.

In a possible implementation, in the aforesaid device provided by the embodiments of the present disclosure, said electric field generating component comprises: an electrode located at a side of said carrier away from said object to be smoothed and a third power source electrically connected to said electrode;

said third power source is used for loading for said electrode a third electric signal having a polarity opposite to that of charges carried by said plasmas.

In a possible implementation, in the aforesaid device provided by the embodiments of the present disclosure, said control component is specifically used for controlling said third power source to decrease an intensity of said third electric signal when said plasmas approach the surface of said object to be smoothed.

In a possible implementation, in the aforesaid device provided by the embodiments of the present disclosure, said plasma generating component comprises a coupling antenna and a three-pin adapter;

said coupling antenna and said three-pin adapter are used for adjusting a distribution of electromagnetic waves within said cavity, such that said electromagnetic waves stimulate gases within said cavity to form plasmas.

In a possible implementation, in the aforesaid device provided by the embodiments of the present disclosure, said cavity comprises two parts separable from each other.

The embodiments of the present disclosure further provide a surface roughness smoothing method, comprising:

placing an object to be smoothed on a carrier within a cavity;

vacuumizing said cavity;

generating, using a plasma generating component, plasmas within said cavity, generating, using a magnetic field generating component, a magnetic field within said cavity which is parallel to a surface of said object to be smoothed, generating, using an electric field generating component, an electric field within said cavity which is perpendicular to the surface of said object to be smoothed.

The embodiments of the present disclosure further provide a thin film transistor comprising a gate, an active layer, a source and a drain, wherein said active layer is a polysilicon layer that has undergone treatment by the aforesaid surface roughness smoothing device provided by the embodiments of the present disclosure.

The embodiments of the present disclosure further provide a display substrate comprising a base substrate and the aforesaid thin film transistor provided by the embodiments of the present disclosure which is located above said base substrate.

The embodiments of the present disclosure further provide a display device comprising the aforesaid display substrate provided by the embodiments of the present disclosure.

The embodiments of the present disclosure provide a smoothing device, a smoothing method, a thin film transistor, a display substrate and a display device. The smoothing device comprises a cavity, a plasma generating component, a magnetic field generating component, an electric field generating component and a carrier located within the cavity. The plasmas generated by the plasma generating component are subjected to the Lorentz force in a direction parallel to the surface of the object to be smoothed under the effect of the magnetic field generated by the magnetic field generating component, and subjected to an electric field force in a direction perpendicular to the surface of the object to be smoothed and pointing to the object to be smoothed under the effect of the electric field generated by the electric field generating component. In this way, the plasmas move towards the object to be smoothed under the co-effect of the Lorentz force and the electric field force, and when the plasmas arrive at the surface of the object to be smoothed, the plasmas are enabled to selectively react with the atoms at convex positions on the object to the smoothed, thereby decreasing the surface roughness of the object to be smoothed without damaging the integral surface of the object to be smoothed.

### BRIEF DESCRIPTION OF DRAWINGS

FIG. 1 is a structural schematic diagram of a surface roughness smoothing device provided by the embodiments of the present disclosure.

FIG. 2 is schematic diagram of the direction of the Lorentz force to which the plasmas are subjected when they arrive at the surface of the object to be smoothed in the surface roughness smoothing device provided by the embodiments of the present disclosure.

FIG. 3 is flow chart of a surface roughness smoothing method provided by the embodiments of the present disclosure.

### DETAILED DESCRIPTION

Specific implementations of the smoothing device, smoothing method, thin film transistor, display substrate and display device provided by the embodiments of the present disclosure are set forth in detail as follows in combination with the figures.

The shapes and sizes of respective components in the figures do not reflect the real scale, the purpose of which is just to illustrate the present disclosure.

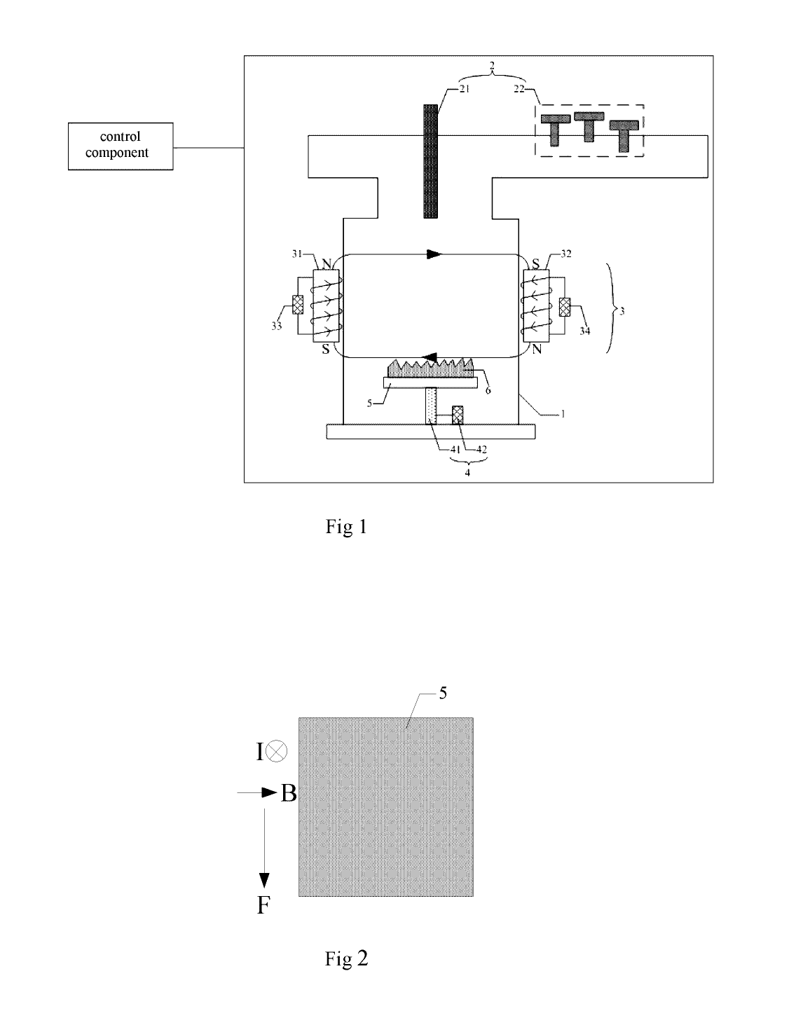

A surface roughness smoothing device provided by the embodiments of the present disclosure comprises, as shown in FIG. 1, a sealed cavity 1, a plasma generating component 2, a magnetic field generating component 3, an electric field generating component 4 and a carrier 5 located within the cavity 1;

the carrier 5 is used for carrying an object to be smoothed 6;

the plasma generating component 2 is used for generating plasmas within the cavity 1;

the magnetic field generating component 3 is used for generating a magnetic field within the cavity 1 which is parallel to the surface of the object to be smoothed 6, such that the plasmas are subjected to the Lorentz force in the direction parallel to the surface of the object to be smoothed 6;

the electric field generating component 4 is used for generating an electric field within the cavity 1 which is perpendicular to the surface of the object to be smoothed 6, such that the plasmas are subjected to an electric field force in the direction perpendicular to the surface of the object to be smoothed 6 and pointing to the object to be smoothed 6.

In the aforesaid surface roughness smoothing device provided by the embodiments of the present disclosure, the plasmas generated by the plasma generating component are subjected to the Lorentz force parallel to the surface of the object to be smoothed under the effect of the magnetic field generated by the magnetic field generating component, and subjected to the electric field force in the direction perpendicular to the surface of the object to be smoothed and pointing to the object to be smoothed under the effect of the electric field generated by the electric field generating component. In this way, the plasmas move towards the object to be smoothed under the co-effect of both the Lorentz force and the electric field force, and when the plasmas arrive at the surface of the object to be smoothed, the plasmas are enabled to selectively react with the atoms at convex positions on the object to be smoothed, thereby decreasing the surface roughness of the object to be smoothed without damaging the integral surface of the object to be smoothed.

Upon implementation, in the aforesaid device provided by the embodiments of the present disclosure, the cavity may comprise two parts separable from each other. For example, the cavity may be provided with a passageway that can be opened and closed. When the passageway is in an open state, the object to be smoothed may be placed into the cavity or the object to be smoothed may be taken out from the cavity; when the passageway is in a closed state, the cavity may be in a sealed state.

Upon implementation, in the aforesaid device provided by the embodiments of the present disclosure, as shown in FIG. 1, the plasma generating component 2 may specifically comprise a coupling antenna 21 and a three-pin adapter 22. By inputting electromagnetic waves and gases into the cavity 1 and adjusting the distribution of the electromagnetic waves in the cavity 1 using the coupling antenna 21 and the three-pin adapter 22, the electromagnetic waves are enabled to stimulate the gases within the cavity 1 to form plasmas. Specifically, gases are generally filled into the cavity 1 when the cavity 1 is in a sealed and vacuum state until the air pressure within the cavity 1 reaches 0.1 Pa, and electromagnetic waves at a frequency of 2.45 GHz stimulate the gases to form plasmas. Specifically, the gases inputted into the cavity 1 may be hydrogen gas (H₂), and the formed plasmas are H⁺; or, the gases inputted into the cavity 1 may also be ammonia gas (NH₃), and the formed plasmas are NH₄⁺; which are not limited here.

Certainly, in the aforesaid device provided by the embodiments of the present disclosure, the specific structure of the plasma generating component is not limited to the structure of a coupling antenna and a three-pin adapter as shown in FIG. 1. The plasma generating component may further be other similar structures capable of generating plasmas within the cavity, which is not limited here.

It needs to be explained that the left hand rule for judging the direction of the Lorentz force acting on the electrified wires in the magnetic field is: opening the left hand, making the thumb perpendicular to the remaining four fingers and making the thumb and the remaining four fingers in the same plane with the palm; enabling the magnetic induction lines to enter from the center of the palm and the four fingers to point to the direction of current. At that time, the direction to which the thumb points is just the direction of the Lorentz force acting on the electrified wires. In the aforesaid device provided by the embodiments of the present disclosure, since the polarity of the plasmas H⁺ or NH₄⁺ generated by the plasma generating component is positive, the movement direction of the plasmas is the direction of current. For example, as shown in FIG. 2, the surface of the object to be smoothed 6 is shown. The movement direction of the plasmas is perpendicular to the surface of the object to be smoothed 6 and points to the object to be smoothed 6, i.e. the movement direction of the plasmas is inward and perpendicular to paper, thus the direction of a current I is inward and perpendicular to paper. Taking the direction of a magnetic field B which is generated by the magnetic field generating component and parallel to the surface of the object to be smoothed 6 being rightward and parallel to paper as an example, in accordance with the left and right hand rules, it can be judged that the direction of the Lorentz force F in the direction parallel to the surface of the object to be smoothed 6, to which the plasmas are subjected, is downward and parallel to paper.

Upon implementation, as shown in FIG. 1, the aforesaid device provided by the embodiments of the present disclosure may further comprise a control component. The control component may be used for controlling the magnetic field generating component 3 to enhance the intensity of the magnetic field when the plasmas approach the surface of the object to be smoothed 6, and simultaneously controlling the electric field generating component 4 to decrease the intensity of the electric field. In this way, when the plasmas approach the surface of the object to be smoothed 6, the Lorentz force in the direction parallel to the surface of the object to be smoothed 6, to which the plasmas are subjected, may be enhanced, such that the moving speed of the plasmas in the direction parallel to the surface of the object to be smoothed 6 becomes faster, thereby enabling the plasmas to selectively and sufficiently react with the atoms at convex positions on the object to be smoothed 6, and at the same time weakening the electric field force in the direction perpendicular to the surface of the object to be smoothed 6 and pointing to the object to be smoothed 6, to which the plasmas are subjected, such that the moving speed of the plasmas in the direction perpendicular to the surface of the object to be smoothed 6 becomes slower, thereby preventing the plasmas from reacting with the atoms at concave positions of the object to be smoothed 6 to avoid damage to the integral surface of the object to be smoothed 6.

It needs to be explained that in the aforesaid device provided by the embodiments of the present disclosure, the control component may determine the time for the plasmas to arrive at the surface of the object to be smoothed depending on the movement distance of the plasmas in the direction perpendicular to the surface of the object to be smoothed and the moving speed thereof, so as to judge whether the plasmas approach the surface of the object to be smoothed. Certainly, the control component may also determine whether the plasmas approach the surface of the object to be smoothed by means of other similar manners, which is not limited here.

Upon implementation, in the aforesaid device provided by the embodiments of the present disclosure, as shown in FIG. 1, the magnetic field generating component 3 may specifically comprise: a first electromagnetic coil 31 and a second electromagnetic coil 32 located at the outer surface of the cavity 1, and a first power source 33 electrically connected to the first electromagnetic coil 31 and a second power source 34 electrically connected to the second electromagnetic coil 32. The first electromagnetic coil 31 is symmetric to the second electromagnetic coil 32 with respect to the central axis of the cavity 1. The first power source 33 is used for loading a first electric signal (generally a current signal) for the first electromagnetic coil 31 such that the first electromagnetic coil 31 generates a magnetic field. The second power source 34 is used for loading a second electric signal (generally a current signal) for the second electromagnetic coil 32 such that the second electromagnetic coil 32 generates a magnetic field in the direction opposite to that of the magnetic field generated by the first electromagnetic coil 31, i.e. enabling the first electromagnetic coil 31 and the second electromagnetic coil 32 to generate magnetic fields in opposite directions, e.g. N pole and S pole of the magnetic field generated by the first electromagnetic coil 31 and N pole and S pole of the magnetic field generated by the second electromagnetic coil 32 as shown in FIG. 1, by controlling the direction (the direction of arrows in the first electromagnetic coil 31 as shown in FIG. 1) of the current loaded by the first power source 33 for the first electromagnetic coil 31 to be opposite to the direction (the direction of arrows in the second electromagnetic coil 32 as shown in FIG. 1) of the current loaded by the second power source 34 for the second electromagnetic coil 32. In this way, there would be a magnetic field between the N pole of the magnetic field generated by the first electromagnetic coil 31 and the S pole of the magnetic field generated by the second electromagnetic coil 32 and between the S pole of the magnetic field generated by the first electromagnetic coil 31 and the N pole of the magnetic field generated by the second electromagnetic coil 32. The magnetic lines of force of the magnetic field can penetrate the cavity 1 such that a magnetic field parallel to the surface of the object to be smoothed 6 is generated within the cavity 1.

Certainly, in the aforesaid device provided by the embodiments of the present disclosure, the specific structure of the magnetic field generating component is not limited to the structures of the two electromagnetic coils shown in FIG. 1. The magnetic field generating component may further be other similar structures capable of generating a magnetic field parallel to the surface of the object to be smoothed within the cavity, which is not limited here.

Upon implementation, as shown in FIG. 1, in the aforesaid device provided by the embodiments of the present disclosure, the control component may specifically be used for controlling the first power source 33 to increase the intensity of the first electric signal and controlling the second power source 34 to increase the intensity of the second electric signal when the plasmas approach the surface of the object to be smoothed 6. In this way, when the plasmas approach the surface of the object to be smoothed 6, the intensity of the magnetic field generated by the first electromagnetic coil 31 and the intensity of the magnetic field generated by the second electromagnetic coil 32 are both enhanced, such that the intensity of the magnetic field parallel to the surface of the object to be smoothed 6 which is generated by the first electromagnetic coil 31 and the second electromagnetic coil 32 together within the cavity 1 is enhanced when the plasmas approach the surface of the object to be smoothed 6. In this way, when the plasmas approach the surface of the object to be smoothed 6, the Lorentz force in the direction parallel to the surface of the object to be smoothed 6, to which the plasmas are subjected, may be enhanced such that the moving speed of the plasmas in the direction parallel to the surface of the object to be smoothed 6 becomes faster, thereby enabling the plasmas to selectively and sufficiently react with the atoms at convex positions on the object to be smoothed 6, further optimizing the surface roughness smoothing effect of the object to be smoothed 6.

Upon implementation, as shown in FIG. 1, in the aforesaid device provided by the embodiments of the present disclosure, the electric field generating component 4 may specifically comprise an electrode 41 located at a side of the carrier 5 away from the object to be smoothed 6 and a third power source 42 electrically connected to the electrode 41. The third power source 42 is used for loading for the electrode 41 a third electric signal (generally a voltage signal) having a polarity opposite to that of the charges carried by the plasmas. Since the polarity of the plasmas H⁺ or NH₄⁺ generated by the plasma generating component 2 is positive, the third power source 42 may load a negative voltage signal for the electrode 41 such that an electric field in the direction perpendicular to the surface of the object to be smoothed 6 and pointing to the object to be smoothed 6 is generated within the cavity 1, thereby enabling the plasmas to be subjected to the electric field force in the direction perpendicular to the surface of the object to be smoothed 6 and pointing to the object to be smoothed 6.

Certainly, in the aforesaid device provided by the embodiments of the present disclosure, the specific structure of the electric field generating component is not limited to the structure of the electrode shown in FIG. 1. The electric field generating component may further be other similar structures capable of generating an electric field within the cavity which is perpendicular to the surface of the object to be smoothed, which is not limited here.

Upon implementation, as shown in FIG. 1, in the aforesaid device provided by the embodiments of the present disclosure, the control component may specifically be used for controlling the third power source 42 to decrease the intensity of the third electric signal when the plasmas approach the surface of the object to be smoothed 6. In this way, when the plasmas approach the surface of the object to be smoothed 6, the intensity of the electric field generated by the electrode 41 is weakened, such that the electric field force in the direction perpendicular to the surface of the object to be smoothed 6 and pointing to the object to be smoothed 6, to which the plasmas are subjected, is weakened when the plasmas approach the surface of the object to be smoothed 6, and the moving speed of the plasmas in the direction perpendicular to the surface of the object to be smoothed 6 becomes slower, thereby preventing the plasmas from reacting with the atoms at concave positions of the object to be smoothed 6 to avoid damage to the integral surface of the object to be smoothed 6, further avoiding negative impact on the performance of the object to be smoothed 6.

It needs to be explained that in the aforesaid device provided by the embodiments of the present disclosure, the plasmas generated by the plasma generating component move towards the object to be smoothed under the co-effect of the Lorentz force and the electric field force. The movement trajectory is not straight. When the plasmas approach the surface of the object to be smoothed, the magnetic field generating component enhances the intensity of the magnetic field while the electric field generating component decreases the intensity of the electric field, such that the moving speed of the plasmas in the direction parallel to the surface of the object to be smoothed becomes faster and the moving speed thereof in the direction perpendicular to the surface of the object to be smoothed becomes slower, thereby enabling the plasmas to selectively and sufficiently react with the atoms at convex positions on the object to be smoothed and preventing the plasmas from reacting with the atoms at concave positions on the object to be smoothed, further achieving the purpose of decreasing the surface roughness of the object to be smoothed without damaging the integral surface of the object to be smoothed. In addition, in the aforesaid device provided by the embodiments of the present disclosure, the magnetic field generating component may not generate a magnetic field while only the electric field generating component generates an electric field before the plasmas approach the surface of the object to be smoothed, so as to enable the plasmas to move towards the object to be smoothed only under the effect of the electric field force. The movement trajectory is straight. When the plasmas approach the surface of the object to be smoothed, the magnetic field generating field generates a magnetic field while the electric field generating component decreases the intensity of the electric field. It is also possible to enable the plasmas to selectively and sufficiently react with the atoms at convex positions on the object to be smoothed and prevent the plasmas from reacting with the atoms at concave positions on the object to be smoothed, thereby achieving the purpose of decreasing the surface roughness of the object to be smoothed without damaging the integral surface of the object to be smoothed.

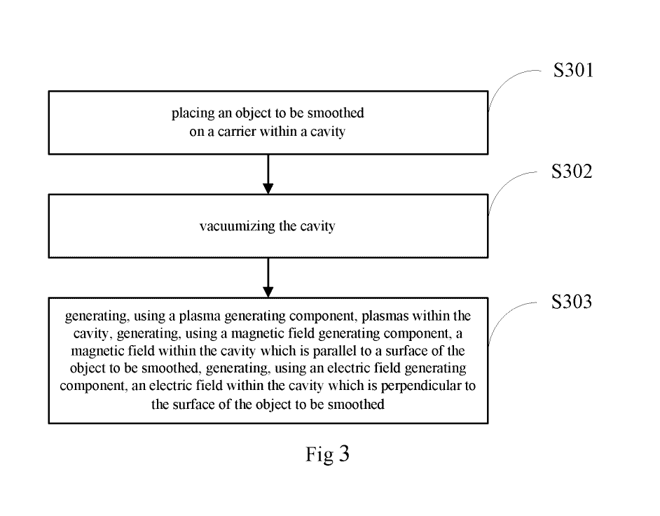

On the basis of the same inventive concept, the embodiments of the present disclosure further provide a surface roughness smoothing method comprising the steps as shown in FIG. 3.

In step S301, an object to be smoothed is placed on a carrier within a cavity.

Specifically, the cavity may comprise two parts separable from each other. Separating the two parts can open the cavity. An object to be smoothed is placed on a carrier within the cavity.

In step S302, the cavity is vacuumized.

Specifically, when the cavity is vacuumized, the cavity is in a sealed state, i.e. the two parts of the cavity are closely attached to each other.

In step S303, a plasma generating component is used to generate plasmas, a magnetic field generating component is used to generate a magnetic field within the cavity which is parallel to the surface of the object to be smoothed, and an electric field generating component is used to generate an electric field within the cavity which is perpendicular to the surface of the object to be smoothed.

The implementation of the surface roughness smoothing method may refer to the embodiment of the aforesaid surface roughness smoothing device, unnecessary details of which are not repeated here.

On the basis of the same inventive concept, the embodiments of the present disclosure further provide a thin film transistor comprising a gate, an active layer, a source and a drain, wherein the active layer is a polysilicon layer that has undergone treatment by the aforesaid surface roughness smoothing device provided by the embodiments of the present disclosure. Performing smoothing of surface roughness of the polysilicon layer in the thin film transistor using the aforesaid device provided by the embodiments of the present disclosure can decrease the surface roughness of the polysilicon layer from about 15 nm to about 7 nm, thereby decreasing the leakage current of the thin film transistor from 1×10⁻¹² A to 1×10⁻¹³ A. Furthermore, the thickness of the gate insulating layer may also be decreased correspondingly, thereby improving the reaction speed of the thin film transistor, increasing the driving current and storage capacitance of the thin film transistor, and alleviating the drift phenomenon of the threshold voltage of the thin film transistor.

On the basis of the same inventive concept, the embodiments of the present disclosure further provide a display substrate comprising a base substrate and the aforesaid thin film transistor provided by the embodiments of the present disclosure which is located above the base substrate. The active layer in the thin film transistor is a polysilicon layer that has undergone treatment by the aforesaid surface roughness smoothing device provided by the embodiments of the present disclosure. Performing smoothing of surface roughness of the polysilicon layer in the thin film transistor using the aforesaid device provided by the embodiments of the present disclosure can decrease the surface roughness of the polysilicon layer from about 15 nm to about 7 nm, thereby decreasing the leakage current of the thin film transistor from 1×10⁻¹² A to 1×10⁻¹³ A. Furthermore, the thickness of the gate insulating layer may also be decreased correspondingly, thereby improving the reaction speed of the thin film transistor, increasing the driving current and storage capacitance of the thin film transistor, and alleviating the drift phenomenon of the threshold voltage of the thin film transistor.

On the basis of the same inventive concept, the embodiments of the present disclosure further provide a display device comprising the aforesaid display substrate provided by the embodiments of the present disclosure. The display device may be any product or component having display function such as mobile phone, tablet computer, television, display, notebook computer, digital frame, navigator, and so on. The implementation of the display device may refer to the embodiment of the aforesaid display substrate, unnecessary details of which are not repeated here.

The embodiments of the present disclosure provide a smoothing device, a smoothing method, a thin film transistor, a display substrate and a display device. The smoothing device comprises a cavity, a plasma generating component, a magnetic field generating component, an electric field generating component and a carrier located within the cavity. The plasmas generated by the plasma generating component are subjected to the Lorentz force parallel to the surface of the object to be smoothed under the effect of the magnetic field generated by the magnetic field generating component, and subjected to an electric field force in the direction perpendicular to the surface of the object to be smoothed and pointing to the object to be smoothed under the effect of the electric field generated by the electric field generating component. In this way, the plasmas move towards the object to be smoothed under the co-effect of the Lorentz force and the electric field force, and when the plasmas arrive at the surface of the object to be smoothed, the plasmas are enabled to selectively react with the atoms at convex positions on the object to the smoothed, thereby decreasing the surface roughness of the object to be smoothed without damaging the integral surface of the object to be smoothed.

Obviously, those skilled in the art can make various modifications and variations to the present disclosure without departing from the spirit and scope of the present disclosure. In this way, if these modifications and variations to the present disclosure pertain to the scope of the claims of the present disclosure and equivalent technologies thereof, the present disclosure also intends to include these modifications and variations.

1. A surface roughness smoothing device comprising: a cavity, a plasma generating component, a magnetic field generating component, an electric field generating component and a carrier located within said cavity; wherein
said carrier is used for carrying an object to be smoothed;
said plasma generating component is used for generating plasmas within said cavity;
said magnetic field generating component is used for generating a magnetic field within said cavity which is parallel to a surface of said object to be smoothed such that said plasmas are subjected to the Lorentz force in a direction parallel to the surface of said object to be smoothed;
said electric field generating component is used for generating an electric field within said cavity which is perpendicular to the surface of said object to be smoothed such that said plasmas are subjected to an electric field force in a direction perpendicular to the surface of said object to be smoothed and pointing to said object to be smoothed.

2. The device according to claim 1, further comprising a control component; wherein
said control component is used for controlling said magnetic field generating component to enhance an intensity of said magnetic field when said plasmas approach the surface of said object to be smoothed, and simultaneously controlling said electric field generating component to decrease an intensity of said electric field.

3. The device according to claim 2, wherein said magnetic field generating component comprises: a first electromagnetic coil and a second electromagnetic coil located at an outer surface of said cavity, and a first power source electrically connected to said first electromagnetic coil and a second power source electrically connected to said second electromagnetic coil; said first electromagnetic coil being symmetric to said second electromagnetic coil with respect to a central axis of said cavity; wherein
said first power source is used for loading a first electric signal for said first electromagnetic coil to enable said first electromagnetic coil to generate a magnetic field;
said second power source is used for loading a second electric signal for said second electromagnetic coil to enable said second electromagnetic coil to generate a magnetic field in a direction opposite to that of the magnetic field generated by said first electromagnetic coil.

4. The device according to claim 3, wherein said control component is used for controlling said first power source to increase an intensity of said first electric signal and controlling said second power source to increase an intensity of said second electric signal when said plasmas approach the surface of said object to be smoothed.

5. The device according to claim 2, wherein said electric field generating component comprises: an electrode located at a side of said carrier away from said object to be smoothed and a third power source electrically connected to said electrode; wherein
said third power source is used for loading for said electrode a third electric signal having a polarity opposite to that of charges carried by said plasmas.

6. The device according to claim 5, wherein said control component is used for controlling said third power source to decrease an intensity of said third electric signal when said plasmas approach the surface of said object to be smoothed.

7. The device according to claim 1, wherein said plasma generating component comprises a coupling antenna and a three-pin adapter; wherein
said coupling antenna and said three-pin adapter are used for adjusting a distribution of electromagnetic waves within said cavity, such that said electromagnetic waves stimulate gases within said cavity to form plasmas.

8. The device according to claim 2, wherein said plasma generating component comprises a coupling antenna and a three-pin adapter; wherein
said coupling antenna and said three-pin adapter are used for adjusting a distribution of electromagnetic waves within said cavity, such that said electromagnetic waves stimulate gases within said cavity to form plasmas.

9. The device according to claim 3, wherein said plasma generating component comprises a coupling antenna and a three-pin adapter; wherein
said coupling antenna and said three-pin adapter are used for adjusting a distribution of electromagnetic waves within said cavity, such that said electromagnetic waves stimulate gases within said cavity to form plasmas.

10. The device according to claim 4, wherein said plasma generating component comprises a coupling antenna and a three-pin adapter; wherein
said coupling antenna and said three-pin adapter are used for adjusting a distribution of electromagnetic waves within said cavity, such that said electromagnetic waves stimulate gases within said cavity to form plasmas.

11. The device according to claim 5, wherein said plasma generating component comprises a coupling antenna and a three-pin adapter; wherein
said coupling antenna and said three-pin adapter are used for adjusting a distribution of electromagnetic waves within said cavity, such that said electromagnetic waves stimulate gases within said cavity to form plasmas.

12. The device according to claim 6, wherein said plasma generating component comprises a coupling antenna and a three-pin adapter; wherein
said coupling antenna and said three-pin adapter are used for adjusting a distribution of electromagnetic waves within said cavity, such that said electromagnetic waves stimulate gases within said cavity to form plasmas.

13. The device according to claim 1, wherein said cavity comprises two parts separable from each other.

14. The device according to claim 2, wherein said cavity comprises two parts separable from each other.

15. The device according to claim 3, wherein said cavity comprises two parts separable from each other.

16. The device according to claim 4, wherein said cavity comprises two parts separable from each other.

17. A surface roughness smoothing method, comprising:
placing an object to be smoothed on a carrier within a cavity;
vacuumizing said cavity;
generating, using a plasma generating component, plasmas within said cavity, generating, using a magnetic field generating component, a magnetic field within said cavity which is parallel to a surface of said object to be smoothed, generating, using an electric field generating component, an electric field within said cavity which is perpendicular to the surface of said object to be smoothed.

18. A thin film transistor comprising a gate, an active layer, a source and a drain, wherein said active layer is a polysilicon layer that has undergone treatment by the surface roughness smoothing device according to claim 1.

19. A display substrate comprising a base substrate and a thin film transistor according to claim 18 which is located above said base substrate.

20. A display device comprising a display substrate according to claim 19.
